(19) United States
(12) Patent Application Publication
(10) Pub. No.: US 2006/0113525 A1
(43) Pub. Date: Jun. 1, 2006

(54) Organic electroluminescent device

(75) Inventors: Min-Ling Hung, Kanding Township (TW); Chung-Wen Ko, Sijhih City (TW); Tswen-Hsin Liu, Jhudong Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/067,767

(22) Filed: Feb. 28, 2005

(30) Foreign Application Priority Data
Nov. 29, 2004 (TW) 93136717

(51) Int. Cl. H01L 29/08; H01M 4/60

(52) U.S. Cl. 257/40; 429/213

(57) ABSTRACT

An organic electroluminescent device comprising a light emitting layer including guest material and host material having formula (I): 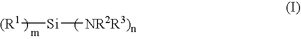
wherein R² and R³ individually represents H or substituent, R¹ represents alkyl, alkenyl, heteroaryl, aryl group with or without substituent, m is an integer of 1 to 3, n is an integer of 1 to 3, and m+n=4.

### BACKGROUND

The invention relates to an organic electroluminescent device (OLED), and more particularly to a host-guest type OLED.

OLED displays are among the most popular displays. When a current passes through it, electrons and holes are induced and the two carriers recombine and release light. The luminescent principle is shown in FIG. 1. The emitting light is fluorescence or phosphorescence. Phosphorescent efficiency is triple of the fluorescent efficiency, thus phosphorescent material is an important OLED material.

Otherwise, a guest material can be added to the light emitting layer to tune light color and luminescent efficiency.

A common host material used in OLEDs is 4,4′-N,N′-dicarbazole-biphenyl (CBP). However, electrons and holes have different transport speed in CBP. This situation decreases OLED carrier recombination efficiency.

To resolve these and other problems, a better host material is desirable.

### SUMMARY

Accordingly, the invention provides an organic electroluminescent device.

An organic electroluminescent device comprises a light emitting layer including guest material and host material having formula (I): 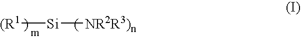
wherein R² and R³ individually represent H or a substituent, R¹ represents alkyl, alkenyl, heteroaryl, aryl group with or without a substituent, m is an integer of 1 to 3, n is an integer of 1 to 3, and m+n=4.

### DESCRIPTION OF THE DRAWINGS

The invention can be more fully understood by reading the subsequent detailed description and examples with references made to the accompanying drawings, wherein:

FIG. 1 is a schematic diagram illustrating the OLED luminescent principle;

FIG. 2 is an OLED cross section of the embodiments;

FIG. 3 shows OLED luminescent efficiency of an example and a comparative example; and

FIG. 4 shows OLED lifetime of an example and a comparative example.

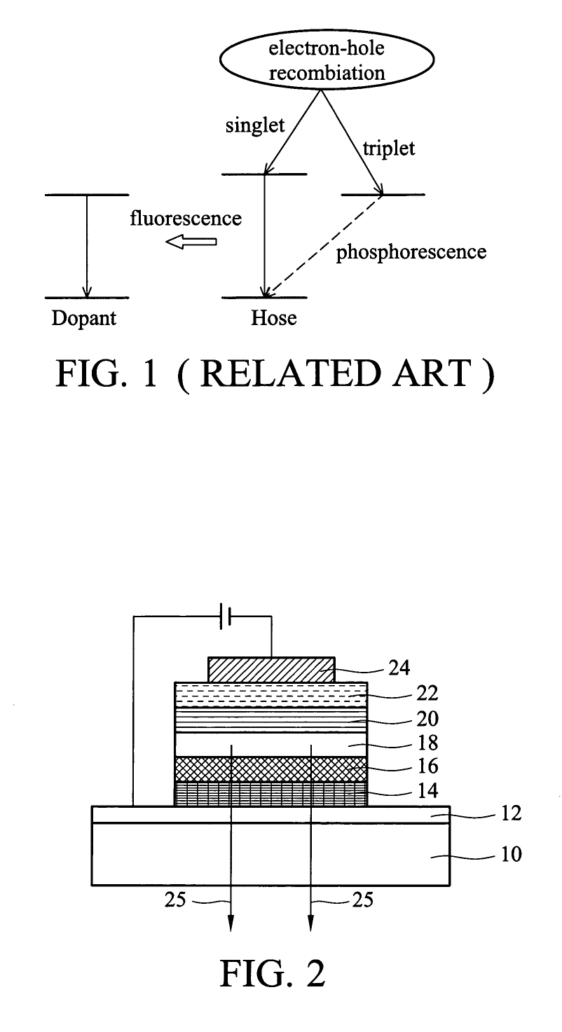

### DETAILED DESCRIPTION

The embodiments provide an OLED as shown in FIG. 2. Anode 12, hole injection layer 14, hole transport layer 16, organic light emitting layer 18, hole blocking layer 20, electron transport layer 22 and a cathode are disposed on substrate 10. Light emitting layer 18 comprises a host material having a silane compound respected by a following formula (I):

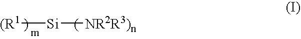

In formula (I), R² and R³ individually represent H or a substituent. The substituent comprises C₁-C₂₀ alkyl, such as methyl, ethyl, isopropyl, tert-butyl, n-octyl, n-decyl, n-hexadecyl, cyclopropryl, cyclopentyl or cyclohexyl groups; C₂-C₂₀ alkenyl; C₂-C₂₀ alkynyl, such as propargyl or 3-pentylnyl groups; C₁-C₂₀ heteroalkyl; C₃-C₄₀ aryl, such as phenyl, o-methylphenyl or naphthyl groups; C₃-C₄₀ heteroaryl, such as carbon atoms on addition to any of oxygen, sulfur or nitrogen atoms, with examples including imidazolyl, pyridyl, furyl, piperidyl, benzoxazolyl, thienyl, triazolyl or carbazolyl groups.

In formula (I), R¹ represents C₁-C₂₀ alkyl, such as methyl, ethyl, isopropyl, n-octyl, n-decyl, n-hexadecyl, cyclopropryl, cyclopentyl or cyclohexyl groups; C₂-C₂₀ alkenyl, such as ethene, propylene, 2-octylene, 3-pentylene groups with or without substituent; C₁-C₅₀ heteroaryl, such as carbon atoms in addition to any of oxygen, sulfur or nitrogen atoms, with examples including imidazolyl, pyridyl, furyl, piperidyl, benzoxazolyl, thienyl or triazolyl groups; C₆-C₃₀ aryl, such as phenyl, p-methylphenyl or naphthyl groups.

In formula (I), m is an integer of 1 to 3, n is an integer of 1 to 3, and m+n=4.

Furthermore, R² and R³ may combine covalently to form heteroaryl group.

Some example of the host materials are as follows:

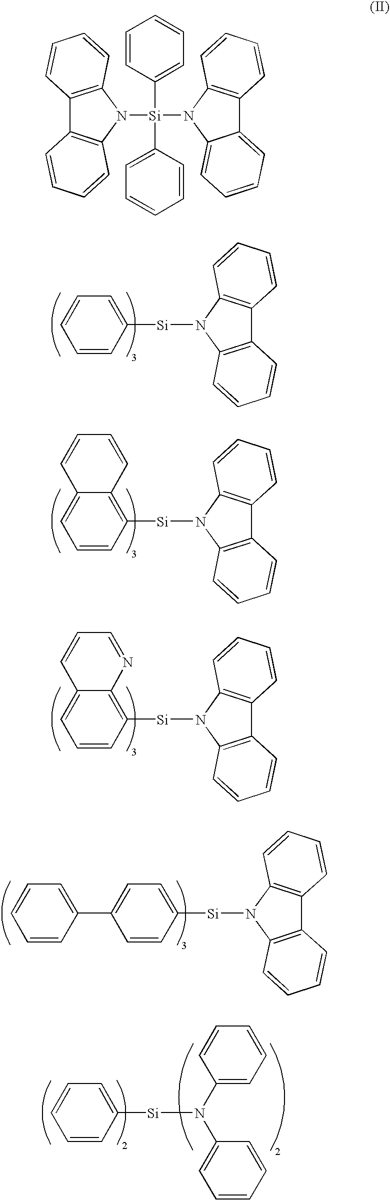

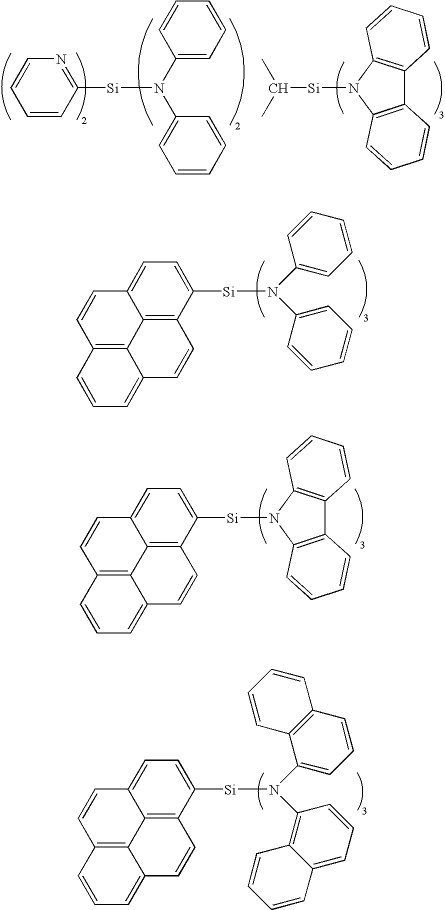

Light emitting layer 18 further comprises a guest material represented by the following formula (III) to emit red, green or blue light: 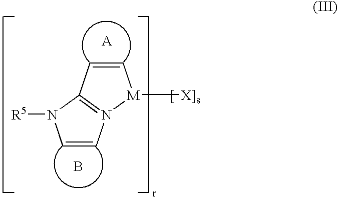
wherein M is a metal having an atomic weight more than 40, r is an integer at least 1, s is an integer at least 0, R⁵ represents H or C₁-C₂₀ alkyl, C₂-C₂₀ alkenyl, C₂-C₂₀ alkynyl, C₁-C₂₀ heteroalkyl, C₃-C₄₀ aryl, C₃-C₄₀ heteroaryl, X represents auxiliary ligand, A represents aryl or heteroaryl group, B represents aryl group.

Some guest materials used with the sliane compound of the invention for emitting red light are as follows: 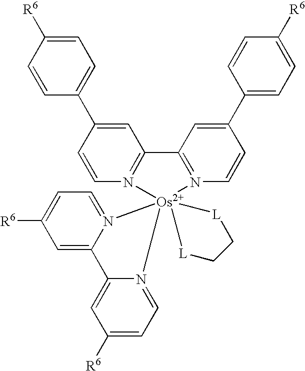
wherein R⁶ represents

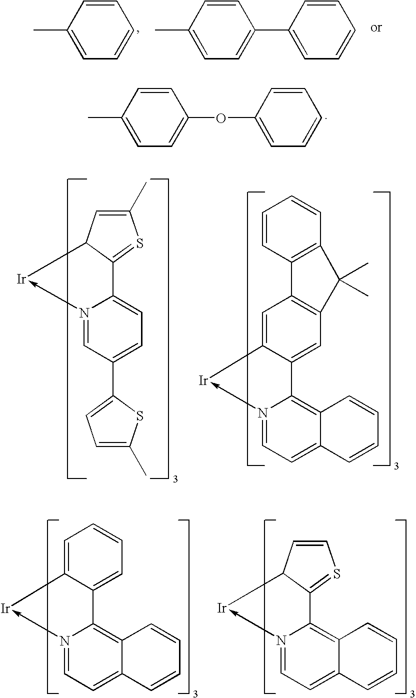

Some guest materials used with the sliane compound of the invention for emitting green light are as follows:

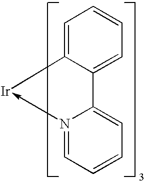

Some guest materials used with the sliane compound of the invention for emitting blue light are as follows:

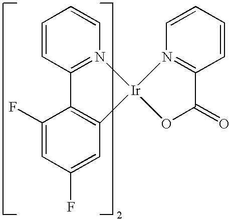

### EXAMPLE

The compound (II) synthesis mechanism is as follows:

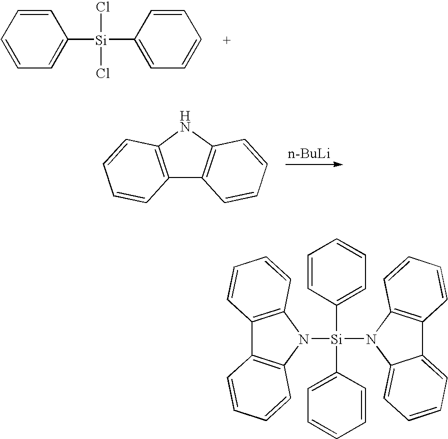

4 g carbazole, 150 ml tetrahydrofurane and 11.1 ml n-Butyllithium were added in a flask under −78° C. 3 g dichlorodiphenylsilane was added in the flask in N₂ and stirred. 200 ml dichloromethane and 200 ml water were added to separate the organic layer. After concentrating and purifying, 5 g white solid was obtained.

Referring to FIG. 2, 60˜80 nm hole injection layer 14, 20˜40 nm hole transport layer 16, 20˜40 nm compound (II) light emitting layer 18, 10˜25 nm hole blocking layer 20, 30˜35 nm electron transport layer 22 were evaporated on the substrate 10 sequentially to form a organic electroluminescent device. The organic light emitting layer 18 is co-dopanted with a guest material.

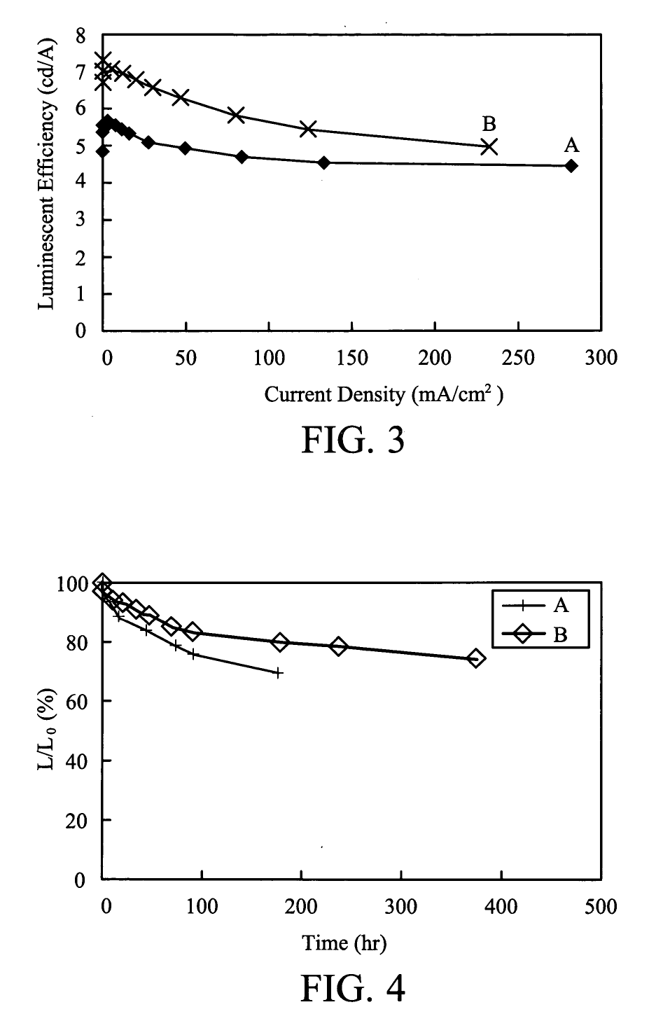

The OLED luminescent efficiency reaches 7.7 cd/A, as shown in FIG. 3 line B. The OLED lifetime is 360 hours for decaying 28%, as shown in FIG. 4 line B.

### Comparative Example

The fabrication of this comparative example OLED is the same with example, except CBP light emitting layer.

The OLED luminescent efficiency reaches 5.5 cd/A, as shown in FIG. 3 line A. The OLED lifetime is 162 hours for decaying 30%, as shown in FIG. 4 line A.

According, the present invention OLED has better luminescent efficiency and longer lifetime than the conventional OLED.

While the invention has been described by way of example and in terms of preferred embodiment, it is to be understood that the invention is not limited thereto.

What is claimed is:

1. An organic electroluminescent device, comprising:
an anode and cathode pair; and
a light emitting layer interposed between the anode and cathode pair, wherein the light emitting layer comprises a host material and guest material, wherein the host material comprises a silane compound respected by a following formula (I): 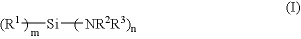
wherein R² and R³ individually represents H or a substituent; R¹ represents alkyl, alkenyl, heteroaryl, or aryl group, each with or without substituent; m is an integer of 1 to 3, n is an integer of 1 to 3, and m+n=4.

2. The organic electroluminescent device as claimed in claim 1, wherein the R² and R³ combine covalently to form heteroaryl.

3. The organic electroluminescent device as claimed in claim 1, wherein the silane compound comprises a following formula (II):

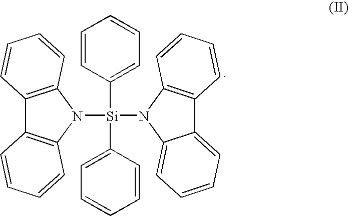

4. The organic electroluminescent device as claimed in claim 1, comprising:
a hole injection layer between the light emitting layer and the anode;
a hole transport layer between the hole injection layer and the light emitting layer;
a hole blocking layer between the light emitting layer and the cathode; and
an electron transport layer between the hole blocking layer and the cathode.

5. The organic electroluminescent device as claimed in claim 1, wherein the guest material comprises a following formula (III): 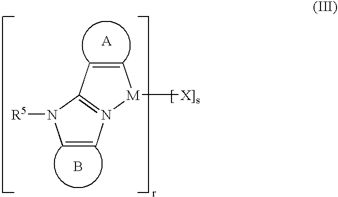
wherein M is a metal having more than 40 atomic weight; r is an integer at least 1; s is an integer at least 0; R⁵ represents H or substituent; X represents auxiliary ligand; A represents aryl or heteroaryl group; B represents aryl group.

6. The organic electroluminescent device as claimed in claim 5, wherein the guest material comprises a following formula: 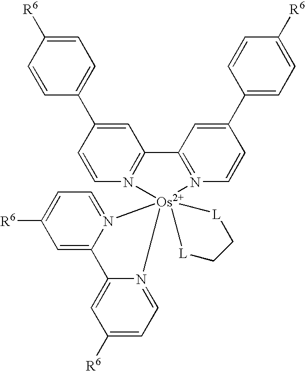
wherein R⁶ represents or

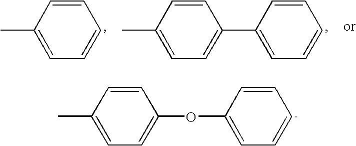

7. The organic electroluminescent device as claimed in claim 5, wherein the guest material comprises the following formula: [chemical structure]
